(19) United States
(12) Patent Application Publication
(10) Pub. No.: US 2017/0194516 A1
(43) Pub. Date: Jul. 6, 2017

(54) ADVANCED DESIGN OF METALLIC GRID IN PHOTOVOLTAIC STRUCTURES

(71) Applicant: SolarCity Corporation, San Mateo, CA (US)

(72) Inventors: Anand J. Reddy, Castro Valley, CA (US); Jiunn Benjamin Heng, Los Altos Hills, CA (US)

(73) Assignee: SolarCity Corporation, San Mateo, CA (US)

(21) Appl. No.: 14/985,223

(22) Filed: Dec. 30, 2015

(51) Int. Cl. H01L 31/0224; H01L 31/0747; H01L 31/02

(52) U.S. Cl. CPC H01L 31/022433; H01L 31/0201; H01L 31/0747

(57) ABSTRACT

One embodiment of the present invention provides a photovoltaic cell. The photovoltaic cell includes a multi-layer semiconductor structure with at least one tapered corner and an electrode that includes a metallic grid having a plurality of finger lines and a single busbar with multiple segments coupled to the finger lines. The single busbar is configured to collect current from the finger lines. The busbar may have a center portion and side portion(s). The side portion(s) may be connected to the center portion forming a non-180-degree angle with the center portion. The finger lines may also be connected to the side portion(s).

### CROSS-REFERENCE TO OTHER APPLICATIONS

This is related to U.S. patent application Ser. No. 14/563,867, Attorney Docket Number P67-3NUS, entitled “HIGH EFFICIENCY SOLAR PANEL,” filed Dec. 8, 2014; and U.S. patent application Ser. No. 14/510,008, Attorney Docket No. P67-2NUS, entitled “MODULE FABRICATION OF SOLAR CELLS WITH LOW RESISTIVITY ELECTRODES,” filed 8 Oct. 2014, the disclosures of which are incorporated herein by reference in their entirety for all purposes.

### FIELD OF THE INVENTION

This disclosure is related to solar cell design including fabrication of solar cells that include advanced metallic grid design.

### DEFINITIONS

A “photovoltaic structure,” refers to a device capable of converting light to electricity. A photovoltaic structure can include a number of semiconductors or other types of materials.

A “solar cell” or “cell” is a type of photovoltaic (PV) structure capable of converting light into electricity. A solar cell may have various sizes and shapes, and may be created from a variety of materials. A solar cell may be a PV structure fabricated on a semiconductor (e.g., silicon) wafer or substrate, or one or more thin films fabricated on a substrate (e.g., glass, plastic, metal, or any other material capable of supporting the photovoltaic structure).

A “finger line,” “finger electrode,” “finger strip,” or “finger” refers to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a PV structure for aggregating current collected by two or more finger lines. A busbar is usually wider than a finger line, and can deposited or otherwise positioned anywhere on or within the photovoltaic structure. A single photovoltaic structure may have one or more busbars.

A “metal grid,” “metallic gird,” or “grid” is a collection of finger lines and one or more busbars. The metal grid fabrication process typically includes depositing or otherwise positioning a layer of metallic material on the photovoltaic structure using various techniques.

A “solar cell strip,” “photovoltaic strip,” or “strip” is a portion or segment of a PV structure, such as a solar cell. A PV structure may be divided into a number of strips. A strip may have any shape and any size. The width and length of a strip may be the same or different from each other. Strips may be formed by further dividing a previously divided strip.

A “cascade” is a physical arrangement of solar cells or strips that are electrically coupled via electrodes on or near their edges. There are many ways to physically connect adjacent photovoltaic structures. One way is to physically overlap them at or near the edges (e.g., one edge on the positive side and another edge on the negative side) of adjacent structures. This overlapping process is sometimes referred to as “shingling.” Two or more cascading photovoltaic structures or strips can be referred to as a “cascaded string,” or more simply as a string.

### BACKGROUND

The negative environmental impact of fossil fuels and their rising cost have resulted in need for cleaner, cheaper alternative energy sources. Among different forms of alternative energy sources, solar power has been favored for its cleanness and wide availability.

A solar cell converts light into electricity using the photovoltaic effect. There are several basic solar cell structures, including a single p-n junction, p-i-n/n-i-p, and multi-junction. A typical single p-n junction structure includes a p-type doped layer and an n-type doped layer. Solar cells with a single p-n junction can be homojunction solar cells or heterojunction solar cells. If both the p-doped and n-doped layers are made of similar materials (materials with equal band gaps), the solar cell is called a homojunction solar cell. In contrast, a heterojunction solar cell includes at least two layers of materials of different bandgaps. A p-i-n/n-i-p structure includes a p-type doped layer, an n-type doped layer, and an intrinsic (undoped) semiconductor layer (the i-layer) sandwiched between the p-layer and the n-layer. A multi-junction structure includes multiple single-junction structures of different bandgaps stacked on top of one another.

In a solar cell, light is absorbed near the p-n junction generating carriers. The carriers diffuse into the p-n junction and are separated by the built-in electric field, thus producing an electrical current across the device and external circuitry. An important metric in determining a solar cell's quality is its energy-conversion efficiency, which is defined as the ratio between power converted (from absorbed light to electrical energy) and power collected when the solar cell is connected to an electrical circuit. High efficiency solar cells are essential in reducing cost to produce solar energies.

In practice, multiple individual solar cells are interconnected, assembled, and packaged together to form a solar panel, which can be mounted onto a supporting structure. Multiple solar panels can then be linked together to form a solar system that generates solar power. Depending on its scale, such a solar system can be a residential roof-top system, a commercial roof-top system, or a ground-mount utility-scale system. Note that, in such systems, in addition to the energy conversion efficiency of each individual cell, the ways cells are electrically interconnected within a solar panel also determine the total amount of energy that can be extracted from each panel. Due to the serial internal resistance resulted from the inter-cell connections an external load can only extract a limited percentage of the total power generated by a solar panel. Therefore, an improved metallic grid design and fabrication process is desired to manufacture reliable, low cost, and high efficiency solar cells.

### SUMMARY

One embodiment of the present invention provides a solar cell. The solar cell can include a photovoltaic structure and a metallic grid on the photovoltaic structure. The metallic grid can also include one or more electroplated metal layers. The metallic grid also includes a busbar, one or more finger lines connected to the busbar. The busbar includes a center and side portions, where the center and side portions form a non-180-degree angle.

In some embodiments, the side portion of the busbar is narrower than the center portion of the busbar.

In some embodiments, the side portion of the busbar is wider than one or more of finger lines.

In some embodiments, the width of the side portion of the busbar is proportional to a number of finger lines connected to the side portion of the busbar.

In some embodiments, the side portion of the busbar varies in width.

In some embodiments, the side portion of the busbar is connected to the center portion at a substantially right angle.

In some embodiments, the photovoltaic cell includes at least one rectangular photovoltaic strip with one or more tapered corner, where the side portion of the busbar is located near the tapered corner of the photovoltaic strip.

In some embodiments, the one or more finger lines are connected to the second portion of the busbar.

In some embodiments, some of the finger lines are not parallel to each other.

In some embodiments, some of the finger lines are curved.

In some embodiments, one or more of the finger lines have two portions that are connected to each other at a non-180-degree angle.

In some embodiments, one or more of the finger lines have two portions that are connected to each other at a right angle.

In some embodiments of the present invention provides a solar strip. The solar strip can include a photovoltaic structure with multiple layers. These layers can include a base layer, one or more quantum tunneling barriers, and one or more metallic grids with different patterns on the photovoltaic structure. The grid patterns can include a busbar having a center portion and at least one side portion connected to the center portion at a non-180-degree angle.

In some embodiments, the solar strip can further include a first grid pattern on a first side of the photovoltaic strip with a first busbar, where a center portion of the first busbar is located on a first edge of the first grid pattern.

In some embodiments, the solar strip can further include a second grid pattern on a second side of the solar cell corresponding to the first grid pattern on the first side, where the second grid pattern includes a second busbar located on a second edge of the second pattern corresponds to an opposite edge of the first edge of the first grid pattern, thereby facilitating bifacial operation of the solar cell.

In some embodiments of the present invention provides a solar panel with multiple solar cells connected in series or parallel, where one or more of the solar cells include a busbar having a center portion and at least one side portion connected to the center portion at a non-180-degree angle.

In some embodiments, the photovoltaic structure includes a transparent conducting oxide (TCO) layer, and the metal adhesive layer is in direct contact with the TCO layer.

In some embodiments, the electroplated metal layers include one or more of a Cu layer, an Ag layer, and a Sn layer.

In some embodiments, the metallic grid further includes a metal seed layer between the electroplated metal layer and photovoltaic structure.

In some embodiments, the metal seed layer is formed using a physical vapor deposition (PVD) technique, including evaporation or sputtering deposition.

In some embodiments, the photovoltaic structure includes a base layer, and an emitter layer above the base layer. The emitter layer includes regions diffused with dopants located within the base layer, a poly silicon layer diffused with dopants situated above the base layer, or a doped amorphous silicon (a-Si) layer above the base layer.

In some embodiments, a back junction solar cell is provided, which includes a base layer, a quantum-tunneling-barrier (QTB) layer situated below the base layer facing away from incident light, an emitter layer situated below the QTB layer, a front surface field (FSF) layer situated above the base layer, a front-side electrode situated above the FSF layer, and a back-side electrode situated below the emitter layer.

### BRIEF DESCRIPTION OF THE FIGURES

FIG. 1 shows a detailed view an exemplary double-sided tunneling heterojunction photovoltaic cell.

FIG. 2A shows a detailed view an exemplary electrode grid of a conventional photovoltaic cell.

FIG. 2B shows a cross-sectional view of an exemplary bifacial photovoltaic cell with a single center busbar per surface.

FIG. 3A shows a detailed view of the front surface of an exemplary bifacial photovoltaic cell with a single edge busbar.

FIG. 3B shows a detailed view of the back surface of an exemplary bifacial photovoltaic cell with a single edge busbar.

FIG. 3C shows a cross-sectional view of an exemplary bifacial photovoltaic cell with a single edge busbar per surface.

FIG. 4A shows a detailed view an exemplary serial connection between two adjacent photovoltaic cells with a single edge busbar per surface.

FIG. 4B shows the side-view of an exemplary string of adjacent edge-overlapped photovoltaic cells.

FIG. 4C shows a detailed view an exemplary photovoltaic panel that includes a plurality of photovoltaic cells connected in series each having one busbar.

FIG. 5 shows a simplified equivalent circuit of a photovoltaic panel with serially connected photovoltaic cells.

FIG. 6 shows a simplified equivalent circuit of a photovoltaic panel with parallelly connected photovoltaic cells.

FIG. 7 shows a detailed view of an exemplary photovoltaic panel configuration.

FIG. 8 shows a detailed view of an exemplary photovoltaic cell string with each photovoltaic cell being divided into multiple photovoltaic strips.

FIG. 9 shows a detailed view of an exemplary photovoltaic panel having multiple photovoltaic strings connected in parallel with each photovoltaic string includes photovoltaic strips.

FIG. 10A shows a detailed view of an exemplary metallic grid pattern on the front surface of a photovoltaic cell.

FIG. 10B shows a detailed view of an exemplary metallic grid pattern on the back surface of a photovoltaic cell.

FIG. 11 shows a detailed view of an exemplary photovoltaic cell with multiple photovoltaic strips each having a metallic sub-grid.

FIG. 12 shows a detailed view of an exemplary photovoltaic cell with multiple photovoltaic strips each having a metallic sub-grid that includes a first modified busbar design, in accordance with an embodiment of the present invention.

FIG. 13 shows a detailed view of an exemplary photovoltaic cell with multiple photovoltaic strips each having a metallic sub-grid that includes a second modified busbar design, in accordance with an embodiment of the present invention.

FIG. 14 shows a detailed view of an exemplary photovoltaic cell with multiple photovoltaic strips each having a metallic sub-grid that includes a third modified busbar design, in accordance with an embodiment of the present invention.

FIG. 15 shows a detailed view of an exemplary photovoltaic cell with multiple photovoltaic strips each having a metallic sub-grid that includes a first modified finger line design, in accordance with an embodiment of the present invention.

FIG. 16 shows a detailed view of an exemplary photovoltaic cell with multiple photovoltaic strips each having a metallic sub-grid that includes a second modified finger line design, in accordance with an embodiment of the present invention.

FIG. 17 shows a detailed view of an exemplary photovoltaic cell with multiple photovoltaic strips each having a metallic sub-grid that includes a third modified finger line design, in accordance with an embodiment of the present invention.

FIGS. 18A-G show an exemplary process of fabricating a photovoltaic panel, in accordance with an embodiment of the present invention.

FIG. 19 presents a flow chart showing the process of fabricating a photovoltaic panel, in accordance with an embodiment of the present invention.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

Embodiments of the present invention provide a highly efficient and cost-effective electrode for PV structures by using special electrode designs that can improve collection of current produced from PV structures. To increase efficiency of photovoltaic structures, at least a portion of a metallic grid can be fabricated using improved designs to cover more of the surface area of a given PV structure. As a result, the current generated by a PV structure can be more efficiently routed and collected using the metallic grid. In some embodiments, busbars and/or finger lines can be modified to have multiple portions that are connected to each other with a non-180-degrees angle. In other embodiments, the size and length of each portion of the busbar can be manipulated to improve the current routing and collection. In other embodiments, one or more bent, curved, and/or slanted finger lines may be used to cover additional surface area of PV structures.

Note that embodiments of the present invention can be particularly useful in electrode design of sub-grids for rectangular-shaped photovoltaic strips having tapered corners.

### Bifacial Tunneling Junction Photovoltaic Cells

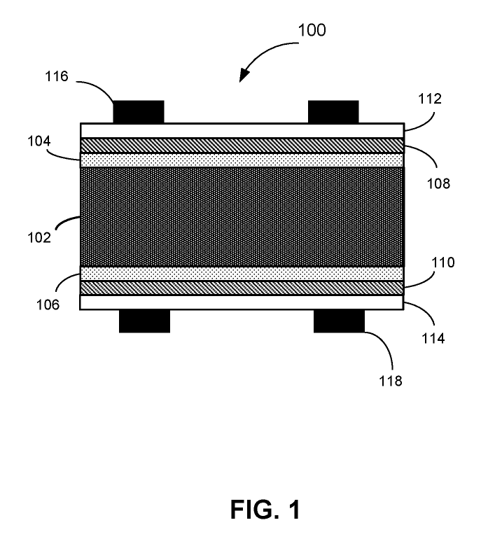

FIG. 1 shows an exemplary double-sided tunneling junction photovoltaic structure. Double-sided tunneling junction photovoltaic structure 100 includes substrate 102, quantum tunneling barrier (QTB) layers 104 and 106 covering opposite surfaces of substrate 102 and passivating the surface-defect states, a front-side doped a-Si layer forming front emitter 108, a back-side doped a-Si layer forming BSF layer 110, front transparent conducting oxide (TCO) layer 112, back TCO layer 114, front metal grid 116, and back metal grid 118. Note that it is also possible to have the emitter layer at the backside and a front surface field (FSF) layer at the front side of the PV structure. Details, including fabrication methods, about double-sided tunneling junction photovoltaic structure 100 can be found in U.S. patent application Ser. No. 12/945,792 (Attorney Docket No. SSP10-1002US), entitled “Solar Cell with Oxide Tunneling Junctions,” by inventors Jiunn Benjamin Heng, Chentao Yu, Zheng Xu, and Jianming Fu, filed 12 Nov. 2010, the disclosure of which is incorporated herein by reference in its entirety herein.

As one can see from FIG. 1, the double-sided tunneling junction PV structure 100 ensures that it can be bifacial given that the backside is exposed to light. In photovoltaic structures, the metallic contacts, such as front and back metallic grids 116 and 118, can collect the current generated by the PV structure. In general, a metallic grid can include two types of metallic lines, including busbars and fingers. More specifically, busbars can be wider metallic lines that are connected directly to external leads (such as metal tabs), while fingers can be finer areas of metalization collecting current for delivery to the busbars.

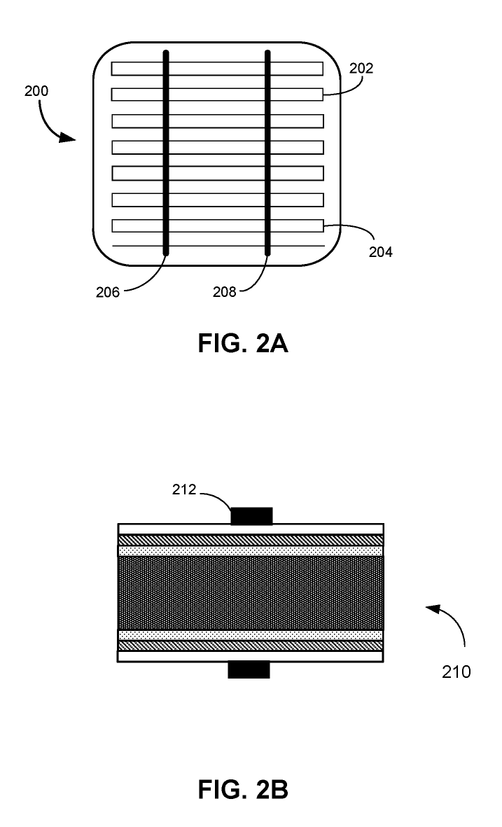

One factor in the metallic grid design is the balance between the increased resistive losses associated with a widely spaced grid and the increased reflection and shading effect caused by a high fraction of metallic coverage of the surface. In conventional PV structures, to prevent power loss due to series resistance of the finger lines, at least two busbars are placed on the surface of the photovoltaic cell to collect current from the fingers, as shown in FIG. 2A. For standardized PV structures, typically two or more busbars at each surface may be needed depending on the resistivity of the electrode materials. Note that in FIG. 2A a surface (which can be the front or back surface) of photovoltaic structure 200 includes a plurality of parallel finger lines, such as finger lines 202 and 204; and two busbars 206 and 208 placed substantially perpendicular to the finger lines. The busbars can be placed in such a way as to ensure that the distance (and hence the resistance) from any point on a finger to a busbar is small enough to minimize power loss. However, these two busbars and the metallic ribbons that are later soldered onto these busbars can create a significant amount of shading, which degrades the photovoltaic structure performance.

In some embodiments, the front and back metallic grids, such as the finger lines, can include electroplated Cu lines. By using an electroplating or electroless plating technique, one can obtain Cu grid lines with a resistivity of equal to or less than 5×10⁻⁶ Ω·cm. In addition, a metal seed layer (such as Ti) can be deposited directly on the TCO layer using, for example, a physical vapor deposition (PVD) process. This seed layer ensures excellent ohmic contact with the TCO layer as well as a strong physical bond with the photovoltaic cell structure. Subsequently, the Cu grid can be electroplated onto the seed layer. This two-layer (seed layer and electroplated Cu layer) ensures excellent ohmic contact quality, physical strength, low cost, and facilitates large-scale manufacturing. Details about an electroplated Cu grid can be found in U.S. patent application Ser. No. 12/835,670 (Attorney Docket No. P52-1NUS), entitled “Solar Cell with Metal Grid Fabricated by Electroplating,” by inventors Jianming Fu, Zheng Xu, Chentao Yu, and Jiunn Benjamin Heng, filed 13 Jul. 2010; and U.S. patent application Ser. No. 13/220,532 (Attorney Docket No. P59-1NUS), entitled “Solar Cell with Electroplated Metal Grid,” by inventors Jianming Fu, Jiunn Benjamin Heng, Zheng Xu, and Chentao Yu, filed 29 Aug. 2011, the disclosures of which are incorporated herein by reference in their entirety herein.

The reduced resistance of the Cu fingers makes it possible to have a metallic grid design that maximizes the overall efficiency of a photovoltaic structure by reducing the number of busbars on its surface. The power loss caused by the increased distance from the fingers to the busbar can be balanced by the reduced shading.

FIG. 2B shows a cross-sectional view of the bifacial photovoltaic structure with a single center busbar per surface. The semiconductor multilayer structure shown in FIG. 2B can be similar to the one shown in FIG. 1. Note that the finger lines are not shown in FIG. 2B because the cut plane cuts between two finger lines. In the example shown in FIG. 2B, busbar 212 runs in and out of the paper, and the finger lines run from left to right. As discussed previously, because there is only one busbar at each surface, the distances from the edges of the fingers to the busbar are longer. However, the elimination of one busbar reduces shading, which not only compensates for the power loss caused by the increased finger-to-busbar distance, but also provides additional power gain. For a standard sized photovoltaic cell, replacing two busbars with a single busbar in the center of the cell can produce an approximately 1.8% power gain.

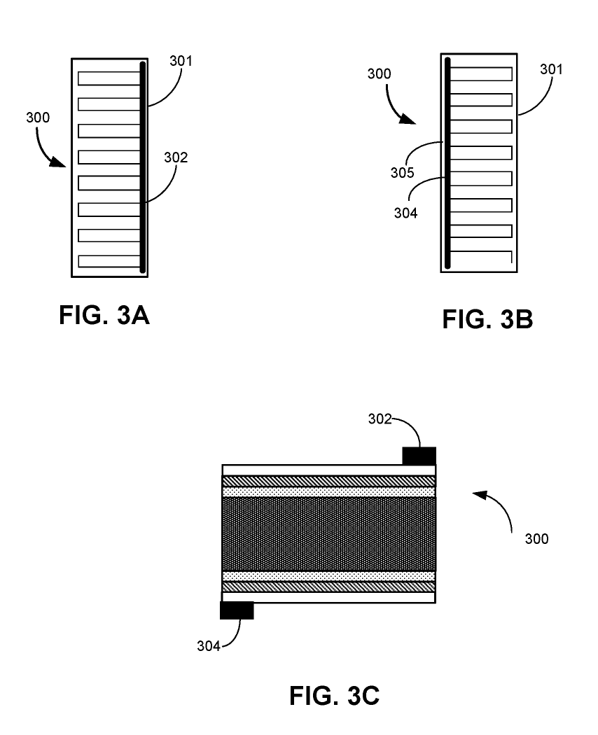

FIG. 3A shows an exemplary bifacial photovoltaic structure. In FIG. 3A, the front surface of photovoltaic structure 300 includes a number of horizontal finger lines and a vertical single busbar 302, which is placed at the right edge of PV structure 300. More specifically, busbar 302 is in contact with the rightmost edge of all the finger lines, and collects current from all the finger lines. FIG. 3B shows the back surface of an exemplary bifacial PV structure. In FIG. 3B, the back surface of PV structure 300 includes a number of horizontal finger lines and a vertical single busbar 304, which is placed at the left edge of PV structure 300. Similar to busbar 302, single busbar 304 is in contact with the leftmost edge of all the finger lines.

FIG. 3C shows a cross-sectional view of the bifacial photovoltaic cell with a single edge busbar per surface. The semiconductor multilayer structure shown in FIG. 3C can be similar to the one shown in FIG. 2B. Like FIG. 2B, in FIG. 3C, the finger lines (not shown) run from left to right, and the busbars run in and out of the paper. From FIGS. 3A-3C, the busbars on the front and the back surfaces of the bifacial PV structures are placed at the opposite edges of the PV structure. This configuration can further improve power gain because the busbar-induced shading now occurs at locations that were less effective in energy production. In general, the edge-busbar configuration can provide at least an approximate 2.1% power gain.

Note that the single busbar per surface configurations (either the center busbar or the edge busbar) not only can provide power gain, but also can reduce fabrication cost, because less metal will be needed for busing ribbons. Moreover, the metal grid on the front sun-facing surface can include parallel metal lines (such as fingers), each having a cross-section with a curved parameter to ensure that incident sunlight on these metal lines is reflected onto the front surface of the photovoltaic cell, thus further reducing shading. Such a shade-free front electrode can be achieved by electroplating Ag- or Sn-coated Cu using a well-controlled, cost-effective patterning scheme.

It is also possible to reduce the power-loss effect caused by the increased distance from the finger edges to the busbars by increasing the aspect ratio of the finger lines. For example, with gridlines with an aspect ratio of 0.5, the power loss could degrade from 3.6% to 7.5% as the gridline length increases from 30 mm to 100 mm. However, with a higher aspect ratio, such as 1.5, the power loss could degrade from 3.3% to 4.9% for the same increase of gridline length. In other words, using high-aspect ratio gridlines can further improve performance. Such high-aspect ratio gridlines can be achieved using an electroplating technique. Details about the shade-free electrodes with high-aspect ratio can be found in U.S. patent application Ser. No. 13/048,804 (Attorney Docket No. P54-1NUS), entitled “Solar Cell with a Shade-Free Front Electrode,” by inventors Zheng Xu, Jianming Fu, Jiunn Benjamin Heng, and Chentao Yu, filed 15 Mar. 2011, the disclosure of which is incorporated herein by reference in its entirety herein.

### Bifacial Photovoltaic Panels Based on Cascaded Strips

Multiple photovoltaic cells with a single busbar (either at the cell center or the cell edge) per surface can be assembled to form a photovoltaic module or panel via a typical panel fabrication process with minor modifications. Based on the locations of the busbars, different modifications to the stringing/tabbing process are needed. In conventional photovoltaic module fabrications, the double-busbar photovoltaic cells are strung together using stringing ribbon(s) (also called tabbing ribbon(s)), which are soldered onto the busbars. More specifically, the stringing ribbons weave from the front surface of one cell to the back surface of the adjacent cell to connect the cells in series. For the single busbar in the cell center configuration, multiple cells with single bubar can be strung or stacked with one another to form a string.

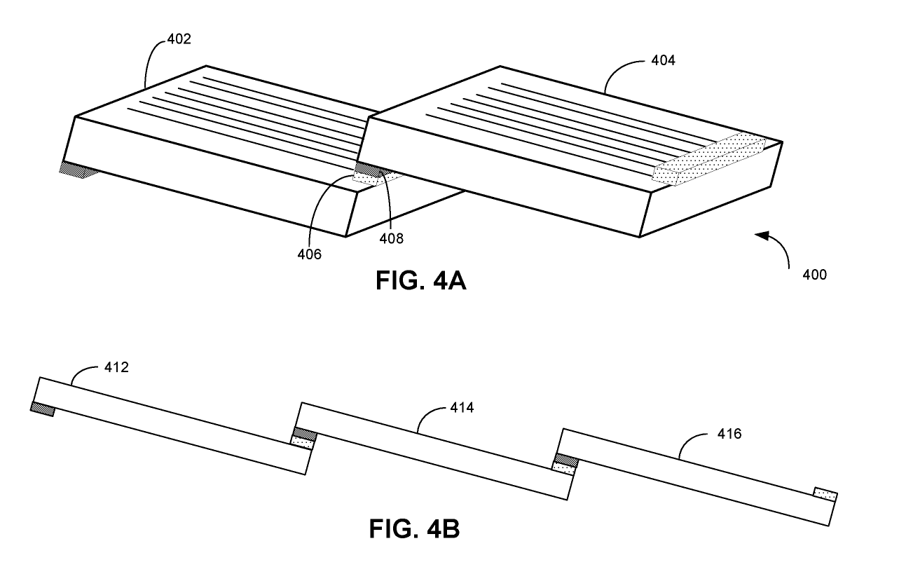

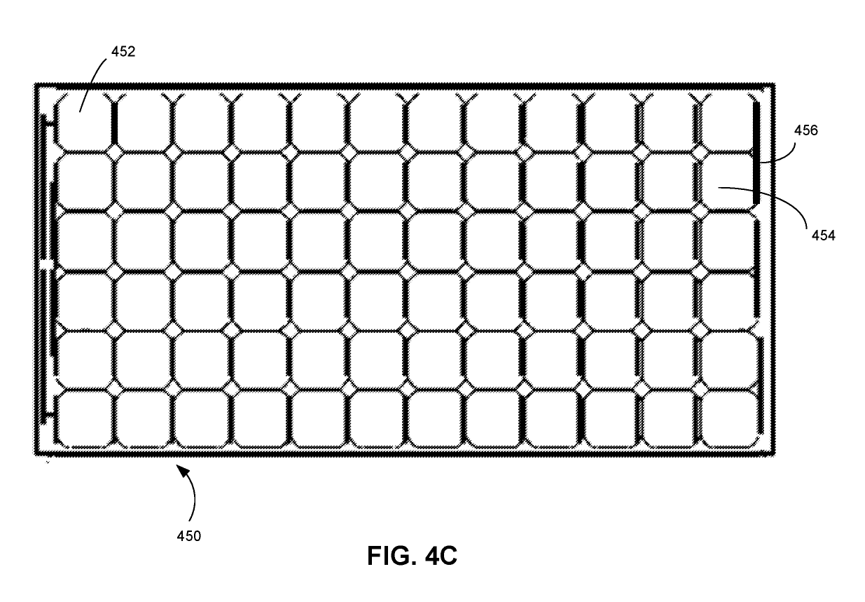

In addition to using a single tab to connect adjacent PV cells in series, the serial connection between adjacent photovoltaic cells is achieved by partially overlapping the adjacent PV cells, thus resulting in the direct contact of the corresponding edge busbars. FIG. 4A shows the serial connection between two adjacent PV cells with a single edge busbar per surface. In FIG. 4A, cell 402 and PV cell 404 are coupled to each other via edge busbar 406 located at the top surface of cell 402 and edge busbar 408 located the bottom surface of PV cell 404. More specifically, the bottom surface of cell 404 partially overlaps with the top surface of photovoltaic cell 402 at the edge in such a way that bottom edge busbar 408 is placed on top of and in direct contact with top edge busbar 406 so that the edge busbars that are in direct contact with each other can be soldered and secured.

FIG. 4B shows the side-view of a string of adjacent edge-overlapped PV cells. In FIG. 4B, PV cell 412 partially overlaps adjacent cell 414, which also partially overlaps (on its opposite end) photovoltaic cell 416. Such a string of photovoltaic cells forms a pattern that is similar to roof shingles. The overlapping should be kept to a minimum to minimize shading caused by the overlapping. Sometimes the single busbars (both at the top and the bottom surface) are placed at the very edge of the PV cell (as shown in FIG. 4B), thus minimizing the overlapping. The same shingle pattern can extend along all photovoltaic cells in a row. To ensure that PV cells in two adjacent rows are connected in series, the two adjacent rows need to have opposite shingle patterns, such as right-side on top for one row and left-side on top for the adjacent row. Moreover, an extra wide metal tab can be used to serially connect the end cells at the two adjacent rows. Detailed descriptions of serially connecting solar cells in a shingled pattern can be found in U.S. patent application Ser. No. 14/510,008 (Attorney Docket No. SSP13-1001CIP), entitled “MODULE FABRICATION OF SOLAR CELLS WITH LOW RESISTIVITY ELECTRODES,” by inventors Jiunn Benjamin Heng, Jianming Fu, Zheng Xu, and Bobby Yang and filed 8 Oct. 2014, the disclosure of which is incorporated herein by reference in its entirety herein.

Note that although the examples above illustrate adjacent solar cells being physically coupled with direct contact in a “shingling” configuration, in some embodiments of the present invention, the adjacent solar cells can also be coupled electrically in series using conductive materials without being in direct contact with one another. FIG. 4C shows photovoltaic panel 450 that includes a plurality of shingled pattern photovoltaic cells. In FIG. 4C, photovoltaic panel 450 includes an array (with 6 rows and 12 cells in a row) of photovoltaic cells. The serial connection is made by the overlapped edge busbars. As a result, when viewing from the top, no busbar can be seen on each PV cell. Therefore, this configuration can also be referred to as the “no-busbar” configuration. In FIG. 4C, at the right end of the rows, an extra wide metal tab 456 couples together the top edge busbar of the end photovoltaic cell of row 452 to the bottom edge busbar of the end cell of row 454. At the left end of the rows, lead wires can be soldered onto the top and bottom edge busbars of the end photovoltaic cells, forming the output electrode of each string with other strings.

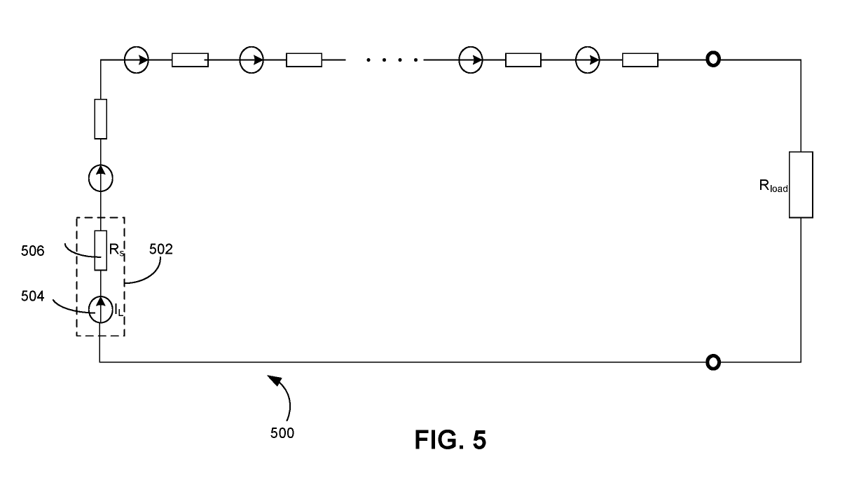

FIG. 5 presents a diagram illustrating a simplified equivalent circuit of a photovoltaic panel with serially connected photovoltaic cells. In FIG. 5, each photovoltaic cell is represented by a current source with an internal resistance. For example, a photovoltaic cell 502 is represented by a current source 504 coupled in series with a resistor 506. When a photovoltaic panel includes serially connected photovoltaic cells, as shown in FIG. 5, the output power of the entire panel is determined by the total generated current (I_{L}_{_}ₜₒₜₐₗ) and the sum of total internal resistance (Rₛ_{_}ₜₒₜₐₗ) and external resistance (i.e., the load resistance, R_{load}). For example, if all photovoltaic cells are identical and receive the same amount of light, for n serially connected photovoltaic cells, I_{L}_{_}ₜₒₜₐₗ=I_{L} and Rₛ_{_}ₜₒₜₐₗ=nRₛ, and the total power generated by the entire circuit can be calculated as Pₒᵤₜ=I_{L}²×(R_{z}_{_}ₜₒₜₐₗ+R_{load}). Assuming that the load resistance R_{load} is adjusted by a maximum power point tracking (MPPT) circuit such that the total resistance for the entire circuit (Rₛ_{_}ₜₒₜₐₗ+R_{load}) allows the entire panel to operate at the maximum power point (which means at a fixed I_{L}_{_}ₜₒₜₐₗ), the amount of power extracted to the external load depends on the total internal resistance Rₛ_{_}ₜₒₜₐₗ. In other words, a portion of the generated power is consumed by the serial internal resistance in the photovoltaic cells themselves: P_{R}=I_{L}²×nR_{S}. That means the less the total internal resistance the entire panel has, the less power is consumed by the photovoltaic cells themselves, and the more power is extracted to the external load.

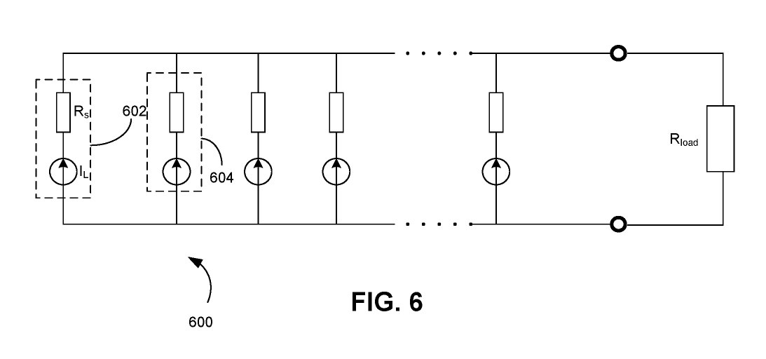

One way to reduce the power consumed by the photovoltaic cells is to reduce the total internal resistance. Various approaches can be used to reduce the series resistance of the electrodes at the cell level. On the panel level, one effective way to reduce the total series resistance is to connect a number of cells in parallel, instead of connecting all the cells within a panel in series. FIG. 6 presents a diagram illustrating a simplified equivalent circuit of a photovoltaic panel with parallelly connected photovoltaic cells, in accordance with one embodiment of the present invention. In the example illustrated in FIG. 6, all photovoltaic cells, such as photovoltaic cells 602 and 604, are connected in parallel. As a result, the total internal resistance of the photovoltaic panel is Rₛ_{_}ₜₒₜₐₗ=Rₛ/n, much smaller than the resistance of each individual photovoltaic cell. However, the output voltage V_{load} is now limited by the open circuit voltage of a single photovoltaic cell, which is difficult in a practical setting to drive load, although the output current can be n times the current generated by a single photovoltaic cell.

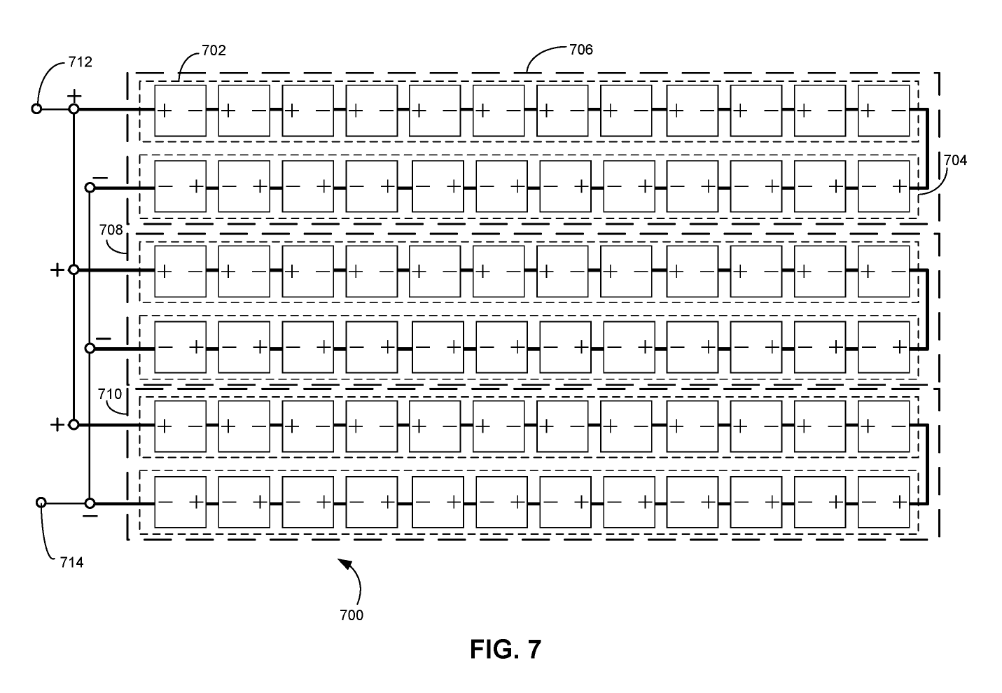

In order to attain an output voltage that is higher than that of the open circuit voltage of a single cell while reducing the total internal resistance for the panel, in some embodiments of the present invention, a subset of photovoltaic cells are connected into a string, and the multiple strings are connected in parallel. In the example shown FIG. 7, photovoltaic cells in top row 702 and second row 704 are connected in series to form a U-shaped string 706. Similarly, the photovoltaic cells in the middle two rows are also connected in series to form a U-shaped string 708, and the photovoltaic cells in the bottom two rows are connected in series as well to form a U-shaped string 710. The three U-shaped strings 706, 708, and 710 are then connected to each other in parallel. More specifically, the positive outputs of all three strings are coupled together to form the positive output 712 of photovoltaic panel 700, and the negative outputs of all strings are coupled together to form the negative output 714 of photovoltaic panel 700.

By serially connecting photovoltaic cells in subsets to form strings and then parallelly connecting the strings, one can reduce the serial resistance of the photovoltaic panel to a fraction of that of a conventional photovoltaic panel with all the cells connected in series. In the example shown in FIG. 7, the cells on a panel are divided into three strings (two rows in each string) and the three strings are parallelly connected, resulting in the total internal resistance of photovoltaic panel 700 being 1/9 of a conventional photovoltaic panel that has all of its 72 cells connected in series. The reduced total internal resistance decreases the amount of power consumed by the photovoltaic cells, and allows more power to be extracted to external loads.

Parallelly connecting the strings also means that the output voltage of the panel is now the same as the voltage across each string, which is a fraction of the output voltage of a photovoltaic panel with all cells connected in series. In the example shown in FIG. 7, the output voltage of panel 700 is ⅓ of a photovoltaic panel that has all of its 72 cells connected in series.

Because the output voltage of each string is determined by the voltage across each photovoltaic cell (which is often slightly less than V_{oc}) and the number of serially connected cells in the string, one can increase the string output voltage by including more cells in each string. However, simply adding more cells in each row will result in an enlarged panel size, which is often limited due to various mechanical factors. Note that the voltage across each cell is mostly determined by V_{oc}, which is independent of the cell size. Hence, it is possible to increase the output voltage of each string by dividing each standard sized (5- or 6-inch) photovoltaic cell into multiple serially connected smaller cells. As a result, the output voltage of each string of photovoltaic cells is increased multiple times.

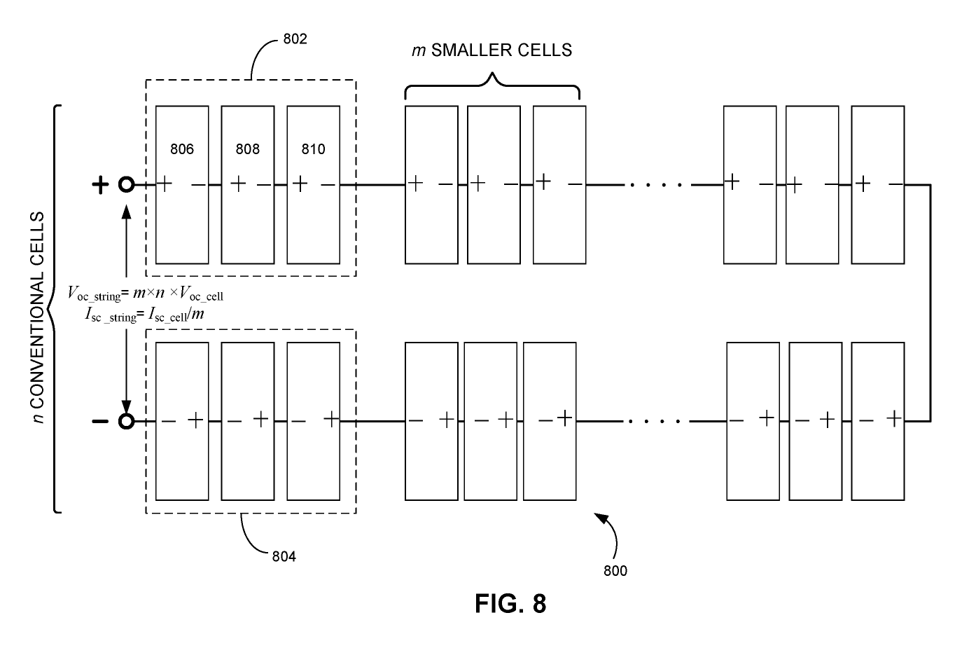

FIG. 8 shows a photovoltaic cell string with each photovoltaic cell being divided into multiple smaller cells, in accordance with an embodiment of the present invention. In the example illustrated in FIG. 8, a photovoltaic cell string 800 includes a number of smaller cells. A conventional photovoltaic cell (such as the one represented by dotted line 802) is replaced by a number of serially connected smaller cells, such as cells 806, 808, and 810. For example, if the conventional photovoltaic cell is a 6-inch square cell, each smaller cell can have a dimension of 2-inch by 6-inch, and a conventional 6-inch square cell is replaced by three 2-inch by 6-inch smaller cells connected in series. Note that, as long as the layer structure of the smaller cells remains the same as the conventional square-sized photovoltaic cell, the smaller cell will have the same V_{oc} as that of the undivided photovoltaic cell. On the other hand, the current generated by each smaller cell is only a fraction of that of the original undivided cell due to its reduced size. Furthermore, the output current by photovoltaic cell string 800 is a fraction of the output current by a conventional photovoltaic cell string with undivided cells. The output voltage of the photovoltaic cell strings is now three times that of a photovoltaic string with undivided cells, thus making it possible to have parallelly connected strings without sacrificing the output voltage.

Now assuming that the open circuit voltage (V_{oc}) across a standard 6-inch photovoltaic cell is V_{oc}_{_}_{cell}, then the V_{oc} of each string is m×n×V_{oc}_{_}_{cell}, wherein m is the number of smaller cells as the result of dividing a conventional square shaped cell, and n is the number of conventional cells included in each string. On the other hand, assuming that the short circuit current (I_{sc}) for the standard 6-inch photovoltaic cell is I_{sc}_{_}_{cell}, then the I_{sc} of each string is I_{sc}_{_}_{cell}/m. Hence, when m such strings are connected in parallel in a new panel configuration, the V_{oc} for the entire panel will be the same as the V_{oc} for each string, and the I_{sc} for the entire panel will be the sum of the I_{sc} of all strings. More specifically, with such an arrangement, one can achieve: V_{oc}_{_}ₚₐₙₑₗ=m×n×V_{oc}_{_}_{cell} and I_{sc}_{_}ₚₐₙₑₗ=I_{sc}_{_}_{cell}. This means that the output voltage and current of this new photovoltaic panel will be comparable to the output voltage and current of a conventional photovoltaic panel of a similar size but with undivided photovoltaic cells all connected in series. The similar voltage and current outputs make this new panel compatible with other devices, such as inverters, that are used by a conventional photovoltaic panel with all its undivided cells connected in series. Although having similar current and voltage output, the new photovoltaic panel can extract more output power to external load because of the reduced total internal resistance.

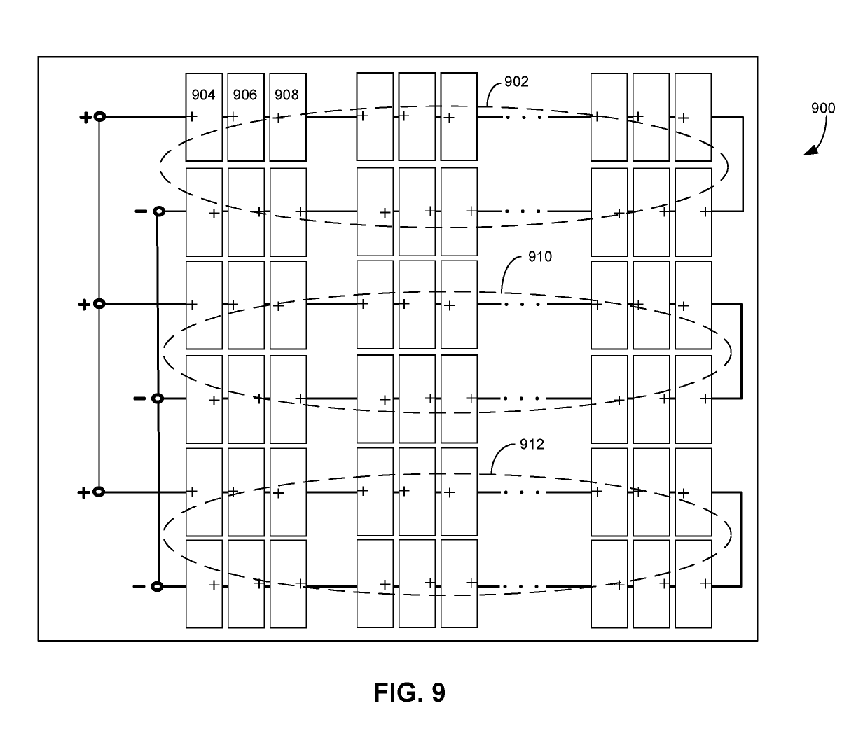

FIG. 9 presents a diagram illustrating an exemplary photovoltaic panel, in accordance with an embodiment of the present invention. In this example, photovoltaic panel 900 includes arrays of photovoltaic cells that are arranged in a repeated pattern, such as a matrix that includes a plurality of rows. In some embodiments, photovoltaic panel 900 can include six rows of inter-connected smaller cells, with each row including 36 smaller cells. Note that each smaller cell is approximately ⅓ of a 6-inch standardized photovoltaic cell. For example, smaller cells 904, 906, and 908 are evenly divided portions of a standard-sized cell. Solar panel 900 is configured in such a way that every two adjacent rows of smaller cells are connected in series, forming three U-shaped strings. In FIG. 9, the top two rows of smaller cells are connected in series to form a photovoltaic string 902, the middle two rows of smaller cells are connected in series to form a photovoltaic string 910, and the bottom two rows of smaller cells are connected in series to form a photovoltaic string 912.

In the example shown in FIG. 9, photovoltaic panel 900 can include three U-shaped strings with each string including 72 smaller cells. The V_{oc} and I_{sc} of the string are 72V_{oc}_{_}_{cell} and I_{sc}_{_}_{cell}/3, respectively; and the V_{oc} and I_{sc} of the panel are 72V_{oc}_{_}_{cell}, and I_{sc}_{_}_{cell}, respectively. Such panel level V_{oc} and I_{sc} are similar to those of a conventional photovoltaic panel of the same size with all its 72 cells connected in series, making it possible to adopt the same circuit equipment developed for the conventional panels.

Furthermore, the total internal resistance of panel 900 is significantly reduced. Assume that the internal resistance of a conventional cell is

The internal resistance of a smaller cell is Rₛₘₐₗₗ_{_}_{cell}=R_{cell}/3. In a conventional panel with 72 conventional cells connected in series, the total internal resistance is 72R_{cell}. In panel 900 as illustrated in FIG. 9, each string has a total internal resistance R_{string}=72 Rₛₘₐₗₗ_{_}_{cell}=24 R_{cell}. Since panel 900 has 3 U-shaped strings connected in parallel, the total internal resistance for panel 900 is R_{string}/3=8 R_{cell}, which is 1/9 of the total internal resistance of a conventional panel. As a result, the amount of power that can be extracted to external load can be significantly increased.

### Advanced Design of Metallic Grid

As one can see, the greater m is, the lower the total internal resistance of the panel can be, and the more power one can extract from the panel. However, a tradeoff is that as m increases, the number of connections required to inter-connect the strings also increases, which can increase the amount of contact resistance. Also, the greater m is, the more strips a single cell may need to be divided into, which may increase the associated production cost and decrease overall reliability due to the larger number of strips used in a single panel.

Another consideration in determining m is the contact resistance between the electrode and the photovoltaic structure on which the electrode is formed. The greater this contact resistance is, the greater m might need to be to reduce effectively the panel's overall internal resistance. Hence, for a particular type of electrode, different values of m might be needed to attain sufficient benefit in reduced total panel internal resistance to offset the increased production cost and reduced reliability. For example, conventional silver-paste or aluminum based electrode may require m to be greater than 4, because the process of screen printing and annealing silver paste on a cell does not produce ideal resistance between the electrode and underlying photovoltaic structure.

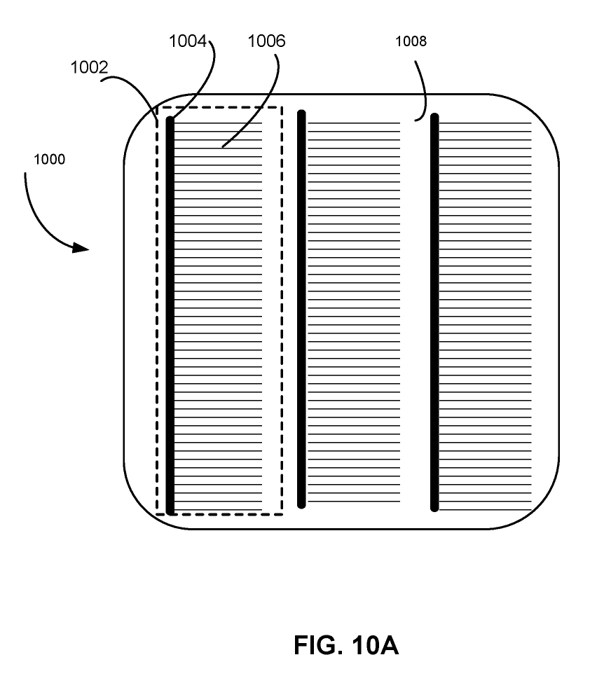

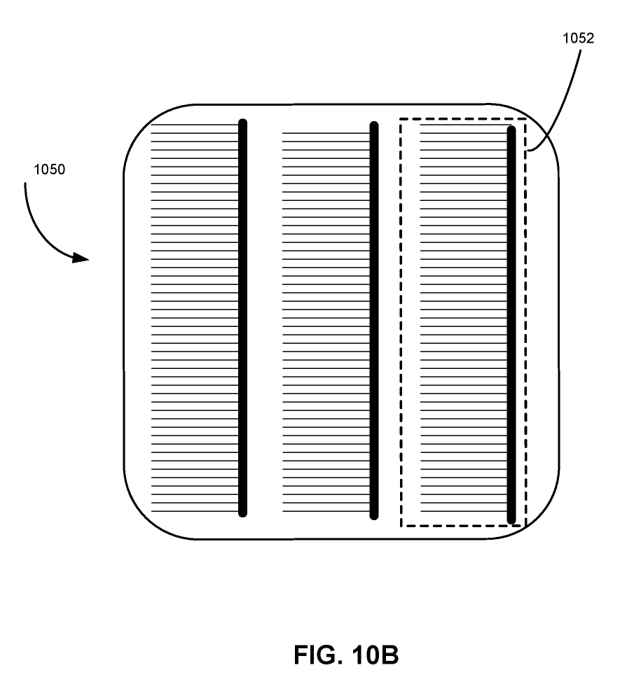

FIG. 10A shows an exemplary grid pattern on a photovoltaic structure, according to one embodiment of the present invention. In the example shown in FIG. 10A, grid 1000 can include three sub-grids, such as sub-grid 1002. This three sub-grid configuration allows the photovoltaic structure to be divided into three strips. To enable cascading, each sub-grid can have an edge busbar. In the example shown in FIG. 10A, each sub-grid can include an edge busbar (“edge” here refers to the edge of a respective strip) along the longer edge of the corresponding strip and a plurality of finger lines running substantially along the shorter edge of the strip. For example, sub-grid 1002 can include edge busbar 1004, and a plurality of finger lines, such as finger line 1006. To facilitate a subsequent scribe-and-cleave process, a predefined blank space (i.e., space not covered by electrodes) can be placed between the adjacent sub-grids. In some embodiments, the width of the blank space, such as blank space 1008, can be between 0.1 mm and 5 mm, preferably between 0.5 mm and 2 mm. There may be a tradeoff between a wider space that leads to more tolerant scribing operation and a narrower space that leads to more effective current collection. In a further embodiment, the width of such a blank space can be approximately 1 mm.

FIG. 10B shows an exemplary grid pattern on the back surface of a photovoltaic structure, according to one embodiment of the invention. In the example shown in FIG. 10B, back grid 1050 can include three sub-grids, such as sub-grid 1052. To enable cascaded and bifacial operation, the back sub-grid can correspond to the front-side sub-grid. More specifically, the back edge busbar can be located at an opposite edge with respect to the corresponding front-side edge busbar. In the examples shown in FIGS. 10A and 10B, the front and back sub-grids have similar patterns except that the front and back edge busbars are located adjacent to opposite edges of the strip. In addition, locations of the blank spaces in back metallic grid 1008 can correspond to locations of the blank spaces in front metallic grid 1000, such that the grid lines do not interfere with the subsequent scribe-and-cleave process. In practice, the finger line patterns on the front- and back-side of the photovoltaic structure may be the same or different.

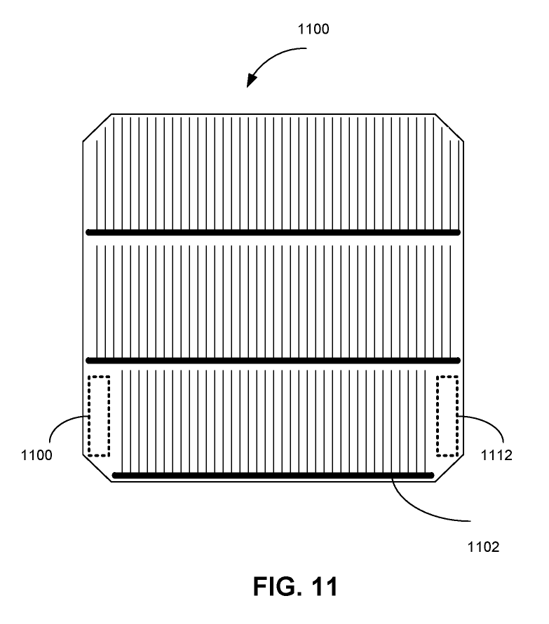

Assuming that the conventional photovoltaic cell is a 6-inch square cell, each sub-grid shown in FIGS. 10A-B can be a 2-inch by 6-inch rectangular shaped PV strip. In other words, a conventional 6-inch square cell is transformed to three 2-inch by 6-inch PV strips that can be connected in series or parallel. However, conventional photovoltaic cells are generally made from a wafer that is sliced from a circular ingot. As a result, conventional photovoltaic cells are generally pseudo squares with tapered corners as shown in FIG. 11. Therefore, not all photovoltaic strips can be a perfect 2-inch by 6-inch rectangular pieces. For example, if the conventional photovoltaic cell is divided equally to produce three identical sub-grids, only the middle piece would be approximately a perfect rectangle, and top and bottom PV strips would be rectangles with tapered corners resulting in pseudo rectangle shaped photovoltaic strips.

This geometric imperfection of top and bottom PV strips within a photovoltaic cell can be troublesome if multiple PV strips are being connected to form a photovoltaic panel using a single edge busbar in each sub-grid of these PV strips. As shown in FIG. 11, busbar 1102 can only be extended to cover the bottom edge of photovoltaic cell 1100 up to the bottom tapered corners, which results in smaller metallic sub-grid at the bottom of photovoltaic cell 1100 in compare with the middle sub-grid of photovoltaic cell 1100. The smaller bottom sub-grid of photovoltaic cell 1100 cannot collect any current generated in areas nearby the bottom tapered corners (e.g. regions 1110 and 1112) of photovoltaic cell 1100, which in turn make the photovoltaic panel made with these PV strips less efficient.

Therefore, in order to maximize the current being collected from this configuration, different metalization designs can be used to include current being generated at regions 1110 and 1112 in the total collected current from PV cell 1100. Hence, a photovoltaic panel that is made with this specific configuration can be more efficient.

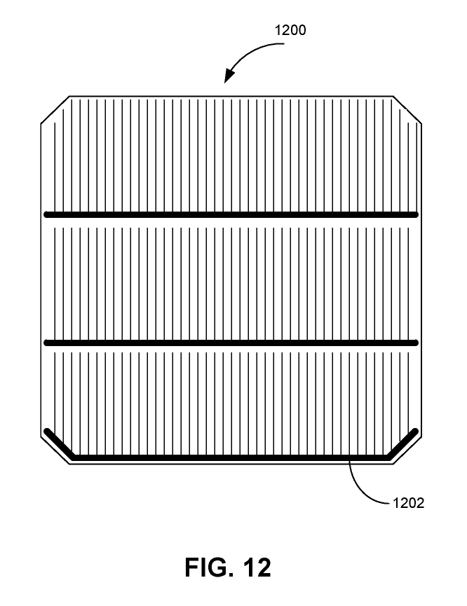

In some embodiments, a modified busbar can be used to cover areas near tapered regions. As shown in FIG. 12, modified busbar 1202 can be used to access areas near the bottom-tapered corners of photovoltaic cell 1200. The modified busbar 1202 can have two distinct portions. A center portion that run along the bottom edge of photovoltaic cell 1200, and side portion(s) that are connected to the center portion and run through areas near the bottom-tapered regions. In some embodiments, the side portion(s) of the modified busbar can be substantially parallel to the tapered section of PV strips. Note that additional finger lines can be added to cover empty corner regions to connect the side portion(s) of the modified busbar. As shown in FIG. 12, these newly added finger lines could be placed substantially parallel to the existing finger lines of the bottom sub-grid for consistency and ease of manufacturing. However, other patterns can be used to implement the newly added finger lines to be connected to the side portion(s) of the modified busbar.

In some embodiments, the side portion(s) of the modified busbar can have different shapes and sizes. In an embodiment, the width of the side portion(s) of the modified busbar can be determined by the number of finger lines being connected to these side portion(s). For example, if there are only a couple of finger lines are being connected to the side portion(s), the width of the side portion(s) may be much thinner than the center portion of the modified busbar and only slightly thicker than a finger line's width. In another example, where there are several finger lines are being connected to the side portion(s), the width of the side portion(s) may be the same or slightly thinner than the center portion of the modified busbar.

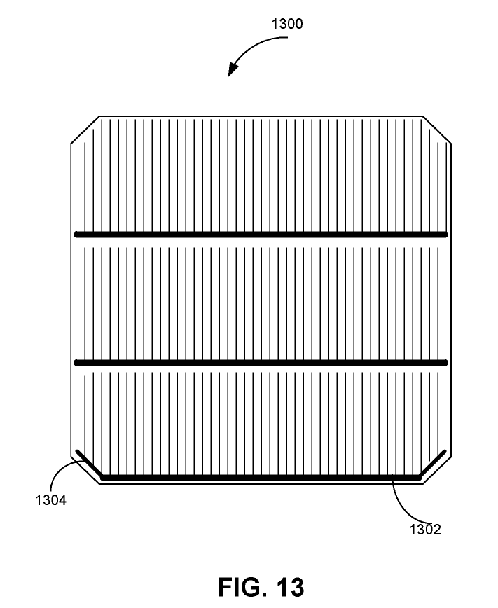

As shown in FIG. 13, the side portion(s) of modified busbar 1302 may have a variable width, in accordance to some embodiments. Variable width side portion(s) 1304 of modified busbar can lower manufacturing cost and shading losses as less metallic material would be used to collect the current generated by PV structures. For example, while one end of side portion(s) connect to the center portion of the modified busbar can be thicker, the opposite end of the side portion(s) can become narrower, as shown in FIG. 13.

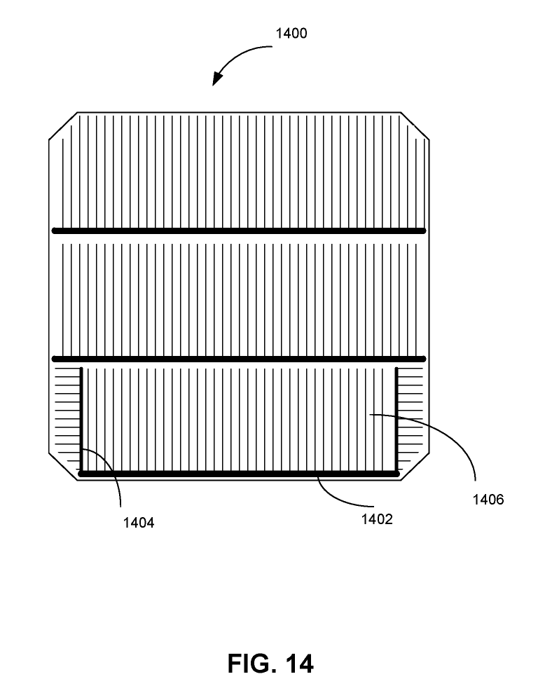

In some embodiments, other metallic grid designs may be used to collect the generated currents near the tapered corners of the bottom sub-grid. For example, the side portion(s) of the busbar in FIG. 14 can make a right angle with the center portion. This way, side portion(s) 1404 of modified busbar 1402 can extend from the bottom edge to the blank space between the bottom sub-grid and the middle sub-grid. In other words, the side portion(s) of the modified busbar can be placed in substantially parallel with the existing finger lines (e.g., finger line 1406) as shown in FIG. 14. Therefore, additional finger lines can be added to the bottom sub-grid to efficiently cover the areas near the bottom-tapered corners of the bottom sub-grid.

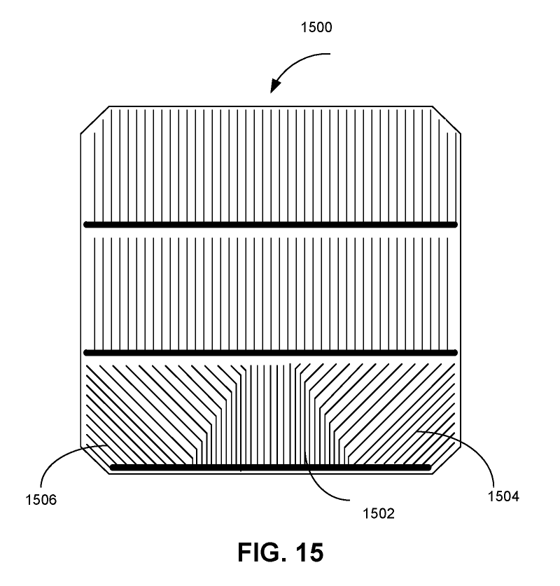

In addition to modified busbars, different finger line patterns may be used to cover areas the bottom-tapered corners. For example, a combination of regular shaped finger lines, slanted finger lines, and bent finger lines can be used as shown in FIG. 15. In some embodiments, regular shaped finger lines can be used in the center of the bottom sub-grid (e.g., finger line 1502), and bent finger lines (which can be thought of a dual portion finger lines) can be used to for the transitional region (i.e. region between the center and corners of the bottom sub-grid) while slanted finger (e.g., finger line 1506) lines are covering the corner regions of the bottom sub-grid.

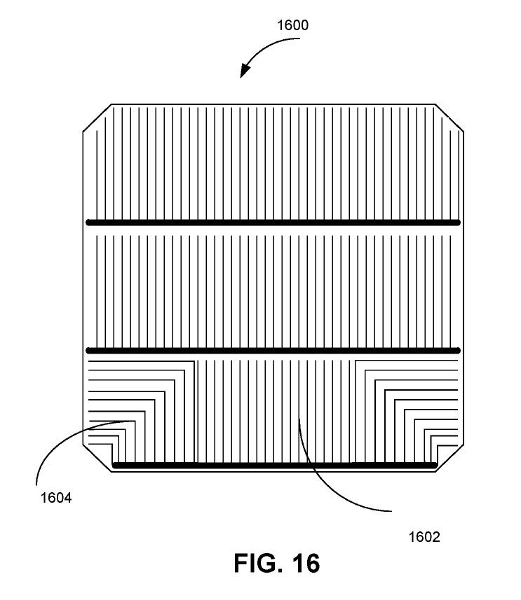

In addition to modified finger lines shown in FIG. 15, there may be additional patterns of modified finger lines covering the tapered portions of the bottom sub-grid. FIG. 16 shows another pattern of modified finger lines, in accordance to an embodiment of the present invention. In FIG. 16, the center region of the sub-grid is covered with regular-shaped finger lines (e.g., finger line 1602) while the side regions of the bottom sub-grid can be covered with modified finger lines (e.g., finger line 1604) with two distinct portions. The first portion of the modified finger lines are connected to the busbar at the right angle while the second portion of the modified finger lines is connected to the first portion at a right angle, parallel to the busbar. Note that the second portions of the modified finger lines may be connected to the first portion at different angles based on the shape and size of the sub-grid corners being covered.

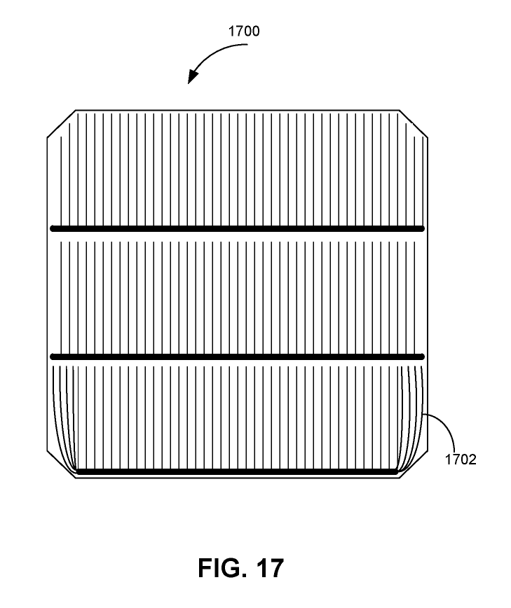

FIG. 17 shows another pattern of modified finger lines covering the tapered regions of the bottom sub-grid, according to an embodiment of the present invention. As shown in FIG. 17, some regions near the bottom-tapered corners can have curved finger lines 1702. Note that most of the finger lines in the sub-grid can still be the regular shaped finger lines except the small regions near the bottom-tapered corners. Because only a small number of finger lines are modified, this method may work best for minimizing the modified manufacturing cost by adding only a single step in manufacturing process. In some embodiments, the curved finger lines may also have a variable width. For example, the curved finger lines can be tapered so that their width is larger as the curved finger lines connect to the busbar, and their width gets smaller as they gets farther from the busbar. In other embodiments, modified curved finger lines can have different curvatures based on the coverage area near the tapered corners.

### Exemplary Fabrication Method I

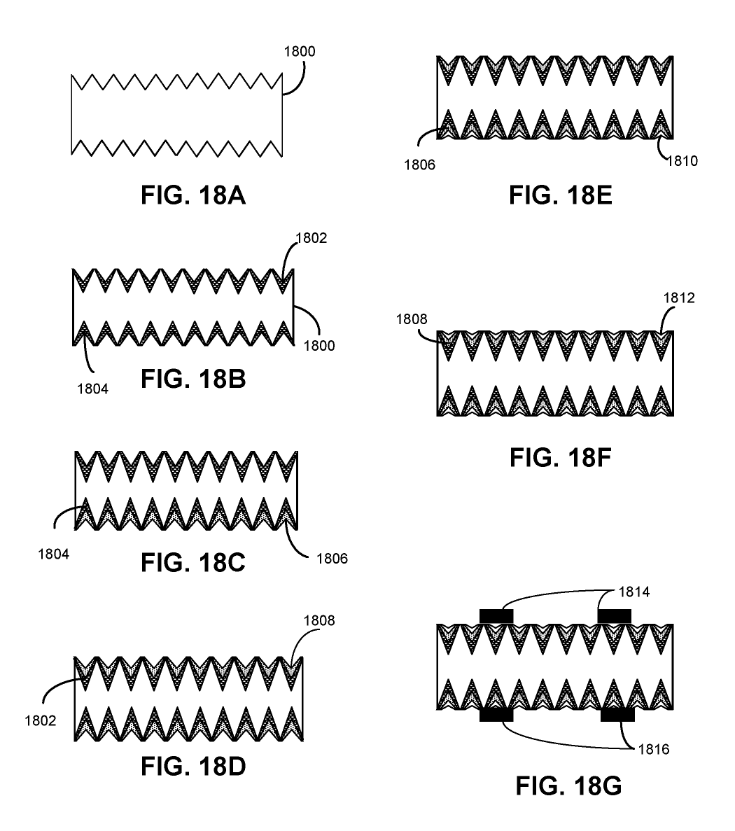

FIGS. 18A-G show an exemplary process of fabricating a photovoltaic structure, according to an embodiment of the present invention.

As shown in FIG. 18A, a substrate 1800 is prepared. In one embodiment, substrate 1800 can be a crystalline-Si (c-Si) wafer. In a further embodiment, preparing c-Si substrate 1800 can include saw damage etch, which removes the damaged outer layer of Si, and surface texturing. The c-Si substrate 1800 can be lightly doped with either n-type or p-type dopants. In one embodiment, c-Si substrate 1800 can be lightly doped with p-type dopants. Note that in addition to c-Si, other materials (e.g., metallurgical-Si) can also be used to form substrate 1800.

As shown in FIG. 18B, a doped emitter layer 1802 is formed on top of c-Si substrate 1800. Depending on the doping type of c-Si substrate 1800, emitter layer 1802 can be either n-type doped or p-type doped. In one embodiment, emitter layer 1802 is doped with n-type dopant. In a further embodiment, emitter layer 1802 is formed by diffusing phosphorous. Note that if phosphorus diffusion is used for forming emitter layer 1802, phosphosilicate glass (PSG) etch and edge isolation can be used. Other methods are also possible to form emitter layer 1802. For example, one can first form a poly Si layer on top of substrate 1800, and then diffuse dopants into the poly Si layer. The dopants can include either phosphorus or boron. Moreover, emitter layer 1802 can also be formed by depositing a doped amorphous Si (a-Si) layer on top of substrate 1800.

As shown in FIG. 18C, an anti-reflection layer 1804 is formed on top of emitter layer 1802. In one embodiment, anti-reflection layer 1804 includes, but not limited to: silicon nitride (SiNₓ), silicon oxide (SiOₓ), titanium oxide (TiOₓ), aluminum oxide (Al₂O₃), and their combinations. In one embodiment, anti-reflection layer 1804 can include a layer of a transparent conducting oxide (TCO) material, such as indium tin oxide (ITO), aluminum zinc oxide (AZO), gallium zinc oxide (GZO), tungsten doped indium oxide (IWO), and their combinations.

As shown in FIG. 18D, back-side electrode 1806 is formed on the back side of Si substrate 1800. In one embodiment, forming back-side electrode 1806 includes printing a full Al layer and subsequent alloying through firing. In one embodiment, forming back-side electrode 1806 can include printing an Ag/Al grid and subsequent furnace firing. In a further embodiment, forming back-side electrode 1806 can include electroplating the printed Ag/Al grid using one or more of a Cu layer, an Ag layer, and a Sn layer.

As shown in FIG. 18E, a number of contact windows, including windows 1808 and 1810, can be formed in anti-reflection layer 1804. In one embodiment, heavily doped regions, such as regions 1812 and 1814 can be formed in emitter layer 1802, directly beneath contact windows 1808 and 1810, respectively. In a further embodiment, contact windows 1808 and 1810 and heavily doped regions 1812 and 1814 are formed by spraying phosphorous on anti-reflection layer 1804, followed by a laser-groove local-diffusion process. Note that operation 18E is optional, and can be performed when anti-reflection layer 1804 is electrically insulating. If anti-reflection layer 1804 is electrically conducting (e.g., when anti-reflection layer 1804 is formed using TCO materials), there is no need to form the contact windows.

As shown in FIG. 18F, a metal adhesive layer 1816 is formed on anti-reflection layer 1804. In one embodiment, materials used to form adhesive layer 1816 include, but are not limited to: Ti, titanium nitride (TiNₓ), titanium tungsten (TiWₓ), titanium silicide (TiSiₓ), titanium silicon nitride (TiSiN), Ta, tantalum nitride (TaNₓ), tantalum silicon nitride (TaSiNₓ), nickel vanadium (NiV), tungsten nitride (WNₓ), Cu, Al, Co, W, Cr, Mo, Ni, and their combinations. In a further embodiment, metal adhesive layer 1816 is formed using a physical vapor deposition (PVD) technique, such as sputtering or evaporation. The thickness of adhesive layer 1816 can range from a few nanometers up to 100 nm. Note that Ti and its alloys tend to form very good adhesion with Si material, and they can form good ohmic contact with heavily doped regions 1812 and 1814. Forming metal adhesive layer 1814 on top of anti-reflection layer 1804 prior to the electroplating process can provide better adhesion to anti-reflection layer 1804 of the subsequently formed layers.

As shown in FIG. 18G, a metal seed layer 1818 can be formed on adhesive layer 1816. Metal seed layer 1818 can include Cu or Ag. The thickness of metal seed layer 1818 can be between 12 nm and 500 nm. In one embodiment, metal seed layer 1818 has a thickness of 100 nm. Like metal adhesive layer 1816, metal seed layer 1818 can be formed using a PVD technique. In one embodiment, the metal used to form metal seed layer 1818 is the same metal that used to form the first layer of the electroplated metal. The metal seed layer provides better adhesion of the subsequently plated metal layer. For example, Cu plated on Cu often has better adhesion than Cu plated on to other materials.

As shown in FIG. 18H, a patterned masking layer 1820 is deposited on top of metal seed layer 1818. The openings of masking layer 1820, such as openings 1822 and 1824, correspond to the locations of contact windows 1808 and 1810, and thus are located above heavily doped regions 1812 and 1814. Note that openings 1822 and 1824 are slightly larger than contact windows 1808 and 1810. Masking layer 1820 can include a patterned photoresist layer, which can be formed using a photolithography technique. In one embodiment, the photoresist layer is formed by screen-printing photoresist on top of the wafer. The photoresist can then be cured. A mask can be laid on the photoresist, and the wafer is exposed to UV light. After the UV exposure, the mask is removed, and the photoresist is developed in a photoresist developer. Openings 1822 and 1824 are formed after developing. The photoresist can also be applied by spraying, dip coating, or curtain coating. Dry film photoresist can also be used. Alternatively, masking layer 1820 can include a layer of patterned silicon oxide (SiO₂). In one embodiment, masking layer 1820 is formed by first depositing a layer of SiO₂ using a low-temperature plasma-enhanced chemical-vapor-deposition (PECVD) technique. In a further embodiment, masking layer 1820 can be formed by dip-coating the front surface of the wafer using silica slurry, followed by screen-printing an etchant that includes hydrofluoric acid or fluorides. Other masking materials are also possible, as long as the masking material is electrically insulating.

Note that masking layer 1820 defines the pattern of the front metallic grid because, during the subsequent electroplating, metal materials can only be deposited on regions above the openings, such as openings 1822 and 1824, defined by masking layer 1820. To ensure higher efficiency and better current collection, the pattern(s) defined by masking layer 1820 include exemplary patterns shown in FIGS. 11-17.

As shown in FIG. 181, one or more layers of metal are deposited at the openings of masking layer 1820 to form a front-side metallic grid 1826. Front-side metallic grid 1826 can be formed using an electroplating technique, which can include electrodeposition, light-induced plating, and/or electroless deposition. In one embodiment, metal seed layer 1818 and/or adhesive layer 1816 are coupled to the cathode of the plating power supply, which can be a direct current (DC) power supply, via an electrode. Metal seed layer 1818 and masking layer 1820, which includes the openings, are submerged in an electrolyte solution which permits the flow of electricity. Note that, because masking layer 1820 is electrically insulating, metals will be selectively deposited into the openings, thus, forming a metallic grid with a pattern corresponding to the one defined by those openings. Depending on the material forming metal seed layer 1818, front-side metallic grid 1826 can be formed using Cu or Ag. For example, if metal seed layer 1818 is formed using Cu, front-side metallic grid 1826 is also formed using Cu. In addition, front-side metallic grid 1826 can include a multilayer structure, such as a Cu/Sn bi-layer structure, or a Cu/Ag bi-layer structure. The Sn or Ag top layer is deposited to assist a subsequent soldering process. When depositing Cu, a Cu plate is used at the anode, and the photovoltaic structure is submerged in the electrolyte suitable for Cu plating. The current used for Cu plating is between 0.1 ampere and 2 amperes for a wafer with a dimension of 125 mm×125 mm, and the thickness of the Cu layer is approximately tens of microns. In one embodiment, the thickness of the electroplated metal layer is between 30 μm and 50 μm.

As shown in FIG. 18J, masking layer 1820 is removed.

As shown in FIG. 18K, portions of adhesive layer 1816 and metal seed layer 1818 that are originally covered by masking layer 1820 are etched away, leaving only the portions that are beneath front-side metallic grid 1826. In one embodiment, wet chemical etching process is used. Note that, because front-side metallic grid 1826 is much thicker (by several magnitudes) than adhesive layer 1816 and metal seed layer 1818, the etching has a negligible effect on front-side metallic grid 1826. In one embodiment, the thickness of the resulting metallic grid can range from 30 μm to 50 μm. The width of the finger strips can be between 10 μm to 200 μm, and the width of the busbars can be between 0.5 to 2 mm. Moreover, the spacing between the finger strips can be between 2 mm and 3 mm.

During fabrication, after the formation of the metal adhesive layer and the seed metal layer, it is also possible to form a patterned masking layer that covers areas that correspond to the locations of contact windows and the heavily doped regions, and etch away portions of the metal adhesive layer and the metal seed layer that are not covered by the patterned masking layer. In one embodiment, the leftover portions of the metal adhesive layer and the metal seed layer form a pattern that is similar to the ones shown in FIGS. 11-17. Once the patterned masking layer is removed, one or more layers of metals can be electroplated to the surface of the photovoltaic structure. On the photovoltaic structure surface, only the locations of the leftover portions of the metal seed layer are electrically conductive, a plating process can selectively deposit metals on top of the leftover portions of metal seed layer.

In the example shown in FIG. 18, the back-side electrode is formed using a conventional printing technique (operation 18D). In practice, the back-side electrode can also be formed by electroplating one or more metal layers on the backside of the photovoltaic structure. In one embodiment, the back-side electrode can be formed using operations that are similar to operations 18F-18K, which include forming a metal adhesive layer, a metal seed layer, and a patterned masking layer on the backside of the substrate. Note that the patterned masking layer on the backside defines the pattern of the back-side metallic grid. In one embodiment, the back-side metallic grid includes variable width finger strips. In a further embodiment, the back-side metallic grid may include exemplary patterns shown in FIGS. 11-17.

### Exemplary Fabrication Method II

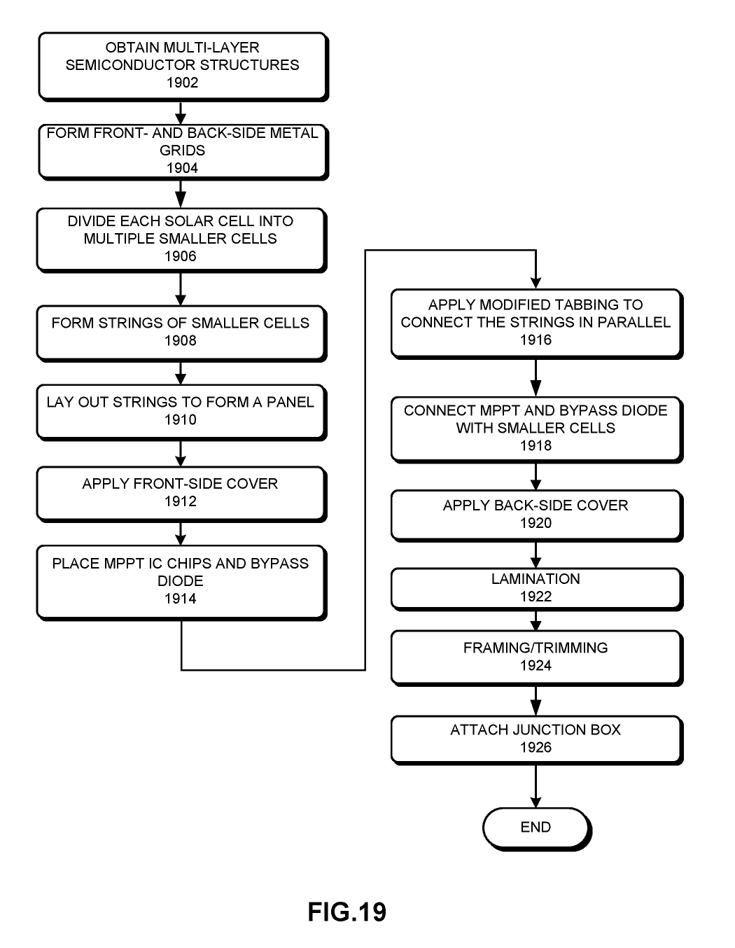

FIG. 19 shows another exemplary process of fabricating a back junction photovoltaic structure with tunneling oxide, according to an embodiment of the present invention.

In operation 19A, a substrate 1900 is prepared. In one embodiment, either n- or p-type doped high-quality solar-grade silicon (SG-Si) wafers can be used to build the back junction photovoltaic cell. In one embodiment, an n-type doped SG-Si wafer is selected. The thickness of SG-Si substrate 1900 can range between 80 and 200 μm. In one embodiment, the thickness of SG-Si substrate 1900 ranges between 90 and 120 μm. The resistivity of SG-Si substrate 1900 can range between 1 Ohm-cm and 10 Ohm-cm. In one embodiment, SG-Si substrate 1900 has a resistivity between 1 Ohm-cm and 2 Ohm-cm. The preparation operation can include typical saw damage etching that removes approximately 10 μm of silicon and surface texturing. The surface texture can have various patterns, including but not limited to: hexagonal-pyramid, inverted pyramid, cylinder, cone, ring, and other irregular shapes. In one embodiment, the surface texturing operation can result in a random pyramid textured surface. Afterwards, SG-Si substrate 1900 goes through extensive surface cleaning.

In operation 19B, a thin layer of high-quality (with Dᵢₜ less than 1×10¹¹/cm²) dielectric material is deposited on the front and back surfaces of SG-Si substrate 1900 to form front and back passivation/tunneling layers 1902 and 1904, respectively. In one embodiment, only the back surface of SG-Si substrate 1900 is deposited with a thin layer of dielectric material. Various types of dielectric materials can be used to form the passivation/tunneling layers, including, but not limited to: silicon oxide (SiOₓ), hydrogenerated SiOₓ, silicon nitride (SiNₓ), hydrogenerated SiNₓ, aluminum oxide (AlOₓ), silicon oxynitride (SiON), and hydrogenerated SiON. In addition, various deposition techniques can be used to deposit the passivation/tunneling layers, including, but not limited to: thermal oxidation, atomic layer deposition, wet or steam oxidation, low-pressure radical oxidation, plasma-enhanced chemical-vapor deposition (PECVD), etc. The thickness of tunneling/passivation layers 1902 and 1904 can be between 1 and 50 angstroms. In one embodiment, the thickness of tunneling/passivation layers 1902 and 1904 is between 1 and 15 angstroms. Note that the well-controlled thickness of the tunneling/passivation layers can ensure good tunneling and passivation effects.

In operation 19C, a layer of hydrogenerated, graded-doping a-Si having a doping type opposite to that of substrate 1900 is deposited on the surface of back passivation/tunneling layer 1904 to form emitter layer 1906. As a result, emitter layer 1906 is situated on the backside of the photovoltaic cell facing away from the incident sunlight. Note that, if SG-Si substrate 1900 is n-type doped, then emitter layer 1906 is p-type doped, and vice versa. In one embodiment, emitter layer 1906 is p-type doped using boron as dopant. SG-Si substrate 1900, back pas sivation/tunneling layer 1904, and emitter layer 1906 form the hetero-tunneling back junction. The thickness of emitter layer 1906 can be between 1 and 20 nm. Note that an optimally doped (with doping concentration varying between 1×10¹⁵/cm³ and 5×10²⁰/cm³) and sufficiently thick (at least between 3 nm and 20 nm) emitter layer can be used to ensure a good ohmic contact and a large built-in potential. In one embodiment, the region within emitter layer 1906 that is adjacent to front passivation/tunneling layer 1902 has a lower doping concentration, and the region that is away from front passivation/tunneling layer 1902 has a higher doping concentration. The lower doping concentration can ensure minimum defect density at the interface between back passivation/tunneling layer 1904 and emitter layer 1906, and the higher concentration on the other side may prevent emitter layer depletion. The work function of emitter layer 1906 can be tuned to better match that of a subsequently deposited back transparent conductive oxide (TCO) layer to enable higher fill factor. In addition to a-Si, it is also possible to use other material, including but not limited to: one or more wide-bandgap semiconductor materials and polycrystalline Si, to form emitter layer 1906.

In operation 19D, a layer of hydrogenerated, graded-doping a-Si having a doping type same as that of substrate 1900 is deposited on the surface of front passivation/tunneling layers 1902 to form front surface field (FSF) layer 1908. Note that, if SG-Si substrate 1900 is n-type doped, then FSF layer 1908 is also n-type doped, and vise versa. In one embodiment, FSF layer 1908 is n-type doped using phosphorous as dopant. SG-Si substrate 1900, front passivation/tunneling layer 1902, and FSF layer 1908 form the front surface high-low homogenous junction that can effectively passivates the front surface. In one embodiment, the thickness of FSF layer 1908 can be between 1 and 30 nm. In one embodiment, the doping concentration of FSF layer 1908 varies from 1×10¹⁵/cm³ to 5×10²⁰/cm³. In addition to a-Si, it is also possible to use other material, including but not limited to: wide-bandgap semiconductor materials and polycrystalline Si, to form FSF layer 1908.

In operation 19E, a layer of TCO material is deposited on the surface of emitter layer 1906 to form a back-side conductive anti-reflection layer 1910, which ensures a good ohmic contact. Examples of TCO include, but are not limited to: indium-tin-oxide (ITO), indium oxide (InO), indium-zinc-oxide (IZO), tungsten-doped indium-oxide (IWO), tin-oxide (SnOₓ), aluminum doped zinc-oxide (ZnO:Al or AZO), Zn—In—O (ZIO), gallium doped zinc-oxide (ZnO:Ga), and other large bandgap transparent conducting oxide materials. The work function of back-side TCO layer 1910 can be tuned to better match that of emitter layer 1906.

In operation 19F, front-side TCO layer 1912 is formed on the surface of FSF layer 1908. Front-side TCO layer 1912 forms a good anti-reflection coating to allow maximum transmission of sunlight into the photovoltaic cell.

In operation 19G, front-side electrode 1914 and back-side electrode 1916 are formed on the surfaces of TCO layers 1912 and 1910, respectively. In one embodiment, front-side electrode 1914 and back-side electrode 1916 include Ag finger grids, which can be formed using various techniques, including, but not limited to: screen printing of Ag paste, inkjet or aerosol printing of Ag ink, and evaporation. In a further embodiment, front-side electrode 1914 and/or back-side electrode 1916 can include Cu grid formed using various techniques, including, but not limited to: electroless plating, electro plating, sputtering, and evaporation. Note that the electrodes on both sides can be formed using various patterns with variable width finger lines. In a further embodiment, the metallic grids of both sides may include exemplary patterns shown in FIGS. 11-17.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

The methods and processes described in the detailed description section can be embodied as code and/or data, which can be stored in a computer-readable storage medium as described above. When a computer system reads and executes the code and/or data stored on the computer-readable storage medium, the computer system can perform the methods and processes embodied as data structures and code and stored within the computer-readable storage medium.

The foregoing descriptions of embodiments of the invention have been presented for purposes of illustration and description only. They are not intended to be exhaustive or to limit the invention to the forms disclosed. Accordingly, many modifications and variations may be apparent to practitioners skilled in the art. Additionally, the above disclosure is not intended to limit the invention. The scope of the invention is defined by the appended claims.

What is claimed is:

1. A photovoltaic cell comprising:
at least one busbar having a center portion formed in a first direction and at least one side portion connected to the center portion and forming a non-180-degree angle with the center portion; and
a plurality of finger lines formed in a second direction and connected to the busbar, wherein the second direction is substantially perpendicular to the first direction.

2. The photovoltaic cell of claim 1, wherein the side portion of the busbar is narrower than the center portion of the busbar.

3. The photovoltaic cell of claim 1, wherein the side portion of the busbar is wider than one or more of the plurality of finger lines.

4. The photovoltaic cell of claim 1, wherein a width of the side portion of the busbar is proportional to a number of the plurality of finger lines connected to the side portion of the busbar.

5. The photovoltaic cell of claim 1, wherein the side portion of the busbar has a variable width.

6. The photovoltaic cell of claim 1, wherein the side portion of the busbar is connected to the center portion at a substantially right angle.

7. The photovoltaic cell of claim 1, wherein the photovoltaic cell includes at least one photovoltaic strip substantially in shape of a rectangle with at least one tapered corner, and wherein the side portion of the busbar is located near the tapered corner of the photovoltaic strip.

8. The photovoltaic cell of claim 1, wherein one or more of the plurality of finger lines are formed in the first direction and connected to the side portion of the busbar.

9. The photovoltaic cell of claim 1, wherein some of the plurality of finger lines are not parallel.

10. The photovoltaic cell of claim 1, wherein one or more of the plurality of finger lines are curved.

11. The photovoltaic cell of claim 10, wherein the photovoltaic cell includes at least one photovoltaic strip substantially in shape of a rectangle with at least one tapered corner, and wherein the one or more of the curved finger lines are formed near the tapered corner of the photovoltaic strip.

12. The photovoltaic cell of claim 1, wherein one or more of the plurality of finger lines are connected to the busbar at a non-180-degree angle.

13. The photovoltaic cell of claim 1, wherein one or more of the plurality of finger lines include a first portion and a second portion, wherein the first and second portions form an obtuse angle.

14. The photovoltaic cell of claim 13, wherein at least one of the first and second portions of the one or more of the plurality of finger lines connects to the busbar at a substantially right angle.

15. The photovoltaic cell of claim 1, wherein one or more of the plurality of finger lines include a first portion and a second portion, wherein the first and second portions form a substantially right angle.

16. A photovoltaic strip, comprising:
a base layer;
a first and second quantum tunneling barrier (QTB) layers deposited on a first and second surfaces of the base layer, respectively;
an amorphous silicon emitter layer;
an amorphous silicon surface field layer; and
at least one metallic grid with one or more grid patterns;
wherein the photovoltaic strip is substantially rectangular shaped; and
wherein the one or more of the grid patterns include at least one busbar having a center portion formed in a first direction and at least one side portion connected to the center portion at a non-180-degree angle.

17. The photovoltaic strip of claim 16, further comprising a first grid pattern on a first side of the photovoltaic strip includes a first busbar, wherein a center portion of the first busbar is located on a first edge of the first grid pattern.

18. The photovoltaic strip of claim 17, further comprising a second grid pattern on a second side of the photovoltaic cell corresponding to the first grid pattern on the first side, wherein the second grid pattern includes a second busbar located on a second edge of the second pattern corresponding to an opposite edge of the first edge of the first grid pattern, thereby facilitating bifacial operation of the photovoltaic cell

19. The photovoltaic strip of claim 16, wherein the at least one metallic grid includes an electroplated copper layer.

20. A photovoltaic panel comprising a plurality of photovoltaic cells connected in at least one of series or parallel configuration, wherein one or more of the photovoltaic cells include:
at least one busbar having a center portion formed in a first direction and at least one side portion connected to the center portion at an obtuse angle; and
a plurality of finger lines formed in a second direction connected to the busbar, wherein the second direction is substantially perpendicular to the first direction.
